(19) United States
(12) Patent Application Publication
(10) Pub. No.: US 2026/0369224 A1
(43) Pub. Date: Nov. 19, 2026

(54) LIGHT EMITTING DEVICE AND DISPLAY DEVICE

(71) Applicant: Sharp Display Technology Corporation, Kameyama City (JP)

(72) Inventor: Nobuo SAITO, Kameyama City, Mie (JP)

(21) Appl. No.: 19/148,294

(22) PCT Filed: Jan. 16, 2023
(86) PCT No.: PCT/JP2023/000992

§ 371 Date: Jul. 15, 2025

(51) Int. Cl. G09G 3/3233; G02B 6/12; H10K 39/34; H10K 59/80

(52) U.S. Cl. CPC G09G 3/3233; H10K 39/34; H10K 59/879; G02B 6/12004; G09G 2300/0426; G09G 2300/0819; G09G 2300/0842; G09G 2300/0861; G09G 2320/02; G09G 2320/045; G09G 2360/142

(57) ABSTRACT

A light-emitting device includes an optical waveguide, a light-emitting element overlapping the optical waveguide in a plan view, and a light-receiving sensor overlapping the optical waveguide and not overlapping the light-emitting element in a plan view.

### TECHNICAL FIELD

The disclosure relates to a light-emitting device and a display device.

### BACKGROUND ART

Predictive compensation of a light-emitting element merely compensates for deterioration over time based on a prediction. Therefore, it is necessary to perform external compensation based on a deterioration state of the light-emitting element, and, in order to optimize the external compensation, a configuration is required in which a light-receiving sensor is provided for each of the light-emitting elements.

PTL 1 discloses a configuration in which an organic EL element is formed on a transparent substrate, and an optical sensor is formed between the transparent substrate and the organic EL element or is formed on a side of the transparent substrate opposite to the organic EL element.

### CITATION LIST

### Patent Literature

PTL 1: JP 2012-186218 A (published on Sep. 27, 2012)

### SUMMARY

### Technical Problem

Normally, since a refractive index of a layer including a light-emitting element is different from an outside refractive index, light emitted at a large angle is reflected at a boundary surface or at a surface, and is not easily extracted to the outside. On the other hand, light emitted at a small angle can be easily extracted to the outside. In the configuration disclosed in PTL 1, since the optical sensor overlaps with the organic EL element in a plan view, a part of light emitted at a small angle enters the optical sensor. Therefore, there is a problem in that an amount of light that is easily extracted is reduced by an amount of the light incident on the optical sensor, and a light extraction efficiency is reduced.

A light-emitting device according to an aspect of the disclosure includes an optical waveguide, a light-emitting element overlapping the optical waveguide in a plan view, and a light-receiving sensor overlapping the optical waveguide and not overlapping the light-emitting element in a plan view.

### Advantageous Effects of Disclosure

According to an aspect of the disclosure, it is possible to improve light extraction efficiency in a light-emitting device that includes a light-emitting element and a light-receiving sensor.

### BRIEF DESCRIPTION OF DRAWINGS

FIG. 1 is a schematic plan view illustrating an example of a configuration of a light-emitting device according to an embodiment of the disclosure.

FIG. 2 is a schematic cross-sectional view illustrating an example of a configuration of a light-emitting device according to the embodiment of the disclosure.

FIG. 3 is a circuit diagram illustrating an example in which circuit configurations of a pixel circuit and a light-receiving circuit illustrated in FIG. 2 are the same.

FIG. 4 is a circuit diagram illustrating an example of an operation when data is written from a data line to the pixel circuit, in the circuit configuration illustrated in FIG. 3.

FIG. 5 is a circuit diagram illustrating an example of an operation when a light-emitting element emits light, in the circuit configuration illustrated in FIG. 3.

FIG. 6 is a circuit diagram illustrating an example in which the circuit configurations of the pixel circuit and the light-receiving circuit illustrated in FIG. 2 are different from each other.

FIG. 7 is a circuit diagram illustrating an example of an operation when data is written from the data line to the pixel circuit, in the circuit configuration illustrated in FIG. 6.

FIG. 8 is a circuit diagram illustrating an example of an operation when the light-emitting element emits light, in the circuit configuration illustrated in FIG. 6.

FIG. 9 is a circuit diagram illustrating an example of an operation when data is read from the light-receiving circuit to the data line, in the circuit configuration illustrated in FIG. 6.

FIG. 10 is a schematic cross-sectional view illustrating an example of a configuration of the light-emitting device according to an embodiment of the disclosure.

FIG. 11 is a schematic cross-sectional view illustrating an example of a configuration of the light-emitting device according to an embodiment of the disclosure.

FIG. 12 is a schematic cross-sectional view illustrating an example of a configuration of the light-emitting device according to an embodiment of the disclosure.

FIG. 13 is a schematic cross-sectional view illustrating an example of a configuration of the light-emitting device according to an embodiment of the disclosure.

FIG. 14 is a schematic cross-sectional view illustrating an example of a configuration of the light-emitting device according to an embodiment of the disclosure.

FIG. 15 is a schematic view illustrating an example of a configuration of a display device according to an embodiment of the disclosure.

FIG. 16 is a schematic plan view illustrating an example of a configuration of a display portion illustrated in FIG. 15.

FIG. 17 is a schematic plan view illustrating another example of a configuration of the display portion illustrated in FIG. 15.

FIG. 18 is a schematic plan view illustrating yet another example of a configuration of the display portion illustrated in FIG. 15.

FIG. 19 is a schematic view illustrating an example of a configuration of the display device according to an embodiment of the disclosure.

### DESCRIPTION OF EMBODIMENTS

### First Embodiment

### Configuration of Light-Emitting Device

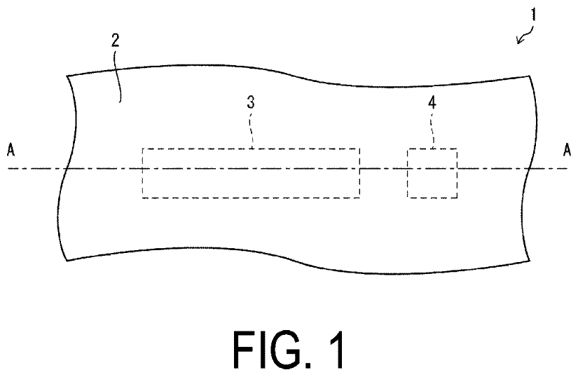

FIG. 1 is a schematic plan view illustrating an example of a configuration of a light-emitting device according to an embodiment of the disclosure. As illustrated in FIG. 1, a light-emitting device 1 includes an optical waveguide 2, a light-emitting element 3 overlapping the optical waveguide 2 in a plan view, and a light-receiving sensor 4 overlapping the optical waveguide 2 in a plan view and not overlapping the light-emitting element 3 in a plan view. The light-emitting element 3 emits light as a result of applying a voltage or a current to the light-emitting element 3. The light-receiving sensor 4 generates photovoltaic power as a result of light being incident on the light-receiving sensor 4.

According to the configuration according to the disclosure, since the light-receiving sensor 4 is located to the side of the light-emitting element 3 in a plan view, light guided by the optical waveguide 2 is incident on the light-receiving sensor 4. Light incident on the optical waveguide 2 from the light-emitting element 3 at an angle smaller than a critical angle traverses the optical waveguide 2 and is easily extracted to the outside. On the other hand, light incident at an angle larger than the critical angle is reflected at the surface of or inside the optical waveguide 2, easily propagates along the optical waveguide 2, and is not easily extracted to the outside. Therefore, advantageously, since the light that is difficult to extract to the outside is incident on the light-receiving sensor 4, the efficiency of extracting the light from the light-emitting device 1 to the outside can be improved.

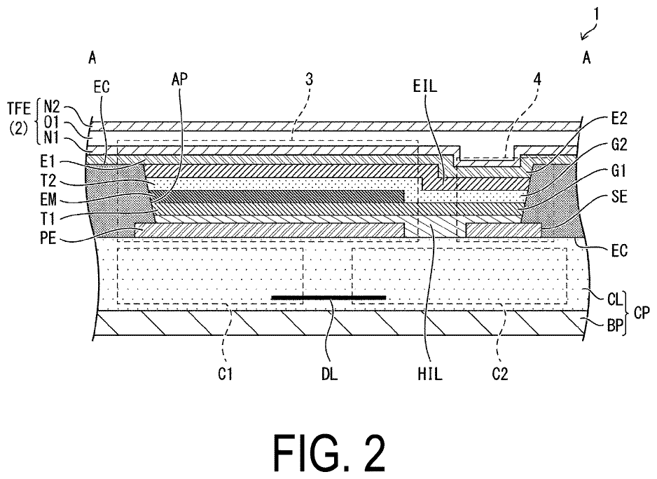

FIG. 2 is a schematic cross-sectional view illustrating an example of a configuration of the light-emitting device according to the embodiment of the disclosure. FIG. 2 corresponds to a cross-sectional view taken along a line A-A in FIG. 1. As illustrated in FIG. 2, the light-emitting element 3 may include a pixel electrode PE overlapping the optical waveguide 2 in a plan view, a first electrode E1 located between the optical waveguide 2 and the pixel electrode PE, and a light-emitting layer EM located between the pixel electrode PE and the first electrode E1. The light-receiving sensor 4 may include a sensor electrode SE overlapping the optical waveguide 2 in a plan view and not overlapping the pixel electrode PE in a plan view, a second electrode E2 located between the optical waveguide 2 and the sensor electrode SE, a first generating layer G1 in which first carriers are generated, the first generating layer G1 being located between the sensor electrode SE and the second electrode E2, and a second generating layer G2 in which second carriers having a polarity opposite to that of the first carriers are generated, the second generating layer G2 being located between the sensor electrode SE and the second electrode E2.

The first carrier is one of a hole and an electron, and the second carrier is the other of the hole and the electron. In the example illustrated in FIG. 1, the first generating layer G1 is a layer in which holes are generated as charge carriers (carrier)(hereinafter referred to as a “hole-generating layer”), and the second generating layer G2 is a layer in which electrons are generated as charge carriers (hereinafter referred to as an “electron-generating layer”). Without being limited to the above example, a configuration in which the first generating layer G1 is an electron-generating layer and the second generating layer G2 is a hole-generating layer is also included in the scope of the disclosure.

The hole-generating layer may include a p-type semiconductor or an organic material having hole transport properties, and the electron-generating layer may include an n-type semiconductor or an electron transport layer organic material. A p-n junction is formed between the hole-generating layer and the electron-generating layer, and when light is incident on or near the p-n junction, one or more pairs of holes and electrons are generated. The first generating layer G1 is preferably in direct contact with the second generating layer G2 in order to increase a generation rate of the hole-electron pairs.

The light-emitting element 3 may include a first transport layer T1 that is located between the pixel electrode PE and the first electrode E1 and that transports the first carriers, and a second transport layer T2 that is located between the pixel electrode PE and the first electrode E1 and that transports the second carriers. The first transport layer T1 may be formed from the same layer made of the same material as the first generating layer G1, and the second transport layer T2 may be formed from the same layer made of the same material as the second generating layer G2. Advantageously, the light-emitting element 3 and the light-receiving sensor 4 share at least some layers, and are thus able to reduce the number of layers of the light-emitting device 1.

In the disclosure, “a certain layer is formed from the same layer as another certain layer” means that it can be presumed that the former layer and the latter layer are formed in the same process. When the material and the thickness of the former layer are substantially the same as the material and the thickness of the latter layer, it can be presumed that the former layer is formed in the same process as the latter layer unless there is any reason to presume that the former layer and the latter layer are formed in different processes.

In the disclosure, “a certain material is substantially the same as another certain material” includes not only a case in which the former material and the latter material completely coincide with each other, but also a case in which the latter material can be obtained by performing arbitrary processing such as doping and exposure on the former material, and a case in which the former material can be obtained by performing arbitrary processing on the latter material.

In the disclosure, “the thickness of a certain layer is substantially the same as the thickness of another certain layer” includes not only a case in which the thickness of the latter layer and the thickness of the former layer completely coincide with each other, but also a case in which a difference between the thickness of the former layer and the thickness of the latter layer is sufficiently small. Usually, a difference of 10% or less of the larger thickness is allowed.

The first transport layer T1 may be continuous with the first generating layer G1, and the second transport layer T2 may be continuous with the second generating layer G2. In other words, the first generating layer G1 and the second generating layer G2 may extend between the pixel electrode PE and the first electrode E1, and may function as the first transport layer T1 and the second transport layer T2, respectively. Advantageously, the layer being continuous from the light-emitting element 3 to the light-receiving sensor 4 can help to guide a portion of the light emitted by the light-emitting element 3 to the light-receiving sensor 4. Without being limited to the above example, the first transport layer T1 may be discontinuous with the first generating layer G1, and the second transport layer T2 may be discontinuous with the second generating layer G2 as a result of film breakage caused by a step or as a result of patterning.

The first transport layer T1 may be located between the pixel electrode PE and the light-emitting layer EM, and a first structure between the pixel electrode PE and the first transport layer T1 may be the same as a second structure between the sensor electrode SE and the first generating layer G1. The second transport layer T2 may be located between the first electrode E1 and the light-emitting layer EM, and a third structure between the first electrode E1 and the second transport layer T2 may be the same as a fourth structure between the second electrode E2 and the second generating layer G2. Advantageously, since the light-emitting element 3 and the light-receiving sensor 4 share more layers, the number of layers of the light-emitting device 1 can be further reduced.

In the disclosure, “the structure between a certain pair of layers is the same as the structure between another certain pair of layers” means the following. First, when there is no layer between the former pair of layers, this means that there is also no layer between the latter pair of layers. Secondly, when there is only one layer between the former pair of layers, this means that there is only one corresponding layer between the latter pair of layers, and that the material and thickness of the one layer between the former pair of layers is substantially the same as the material and thickness of the one layer between the latter pair of layers. Thirdly, when n layers (n is an integer of 2 or more) are overlapped between the former pair of layers, this means that the corresponding n layers are overlapped between the latter pair of layers in the same order, and that the material and the thickness of each of the layers between the former pair of layers are substantially the same as the material and the thickness of the corresponding layers between the latter pair of layers.

The first structure may be continuous with the second structure. Further, the third structure may be continuous with the fourth structure. This advantageously allows more layers to be continuous from the light-emitting element 3 to the light-receiving sensor 4, which can help to guide a portion of the light emitted by the light-emitting element 3 to the light-receiving sensor 4. For example, a hole injection layer HIL may be continuous between the pixel electrode PE and the first transport layer T1 and between the sensor electrode SE and the first generating layer G1. Further, for example, an electron injection layer EIL may be continuous between the first electrode E1 and the second transport layer T2 and between the second electrode E2 and the second generating layer G2.

The sensor electrode SE may be electrically separated from the pixel electrode PE, and the second electrode E2 may be electrically connected to the first electrode E1. Thus, light emission of the light-emitting element 3 and light reception of the light-receiving sensor 4 can be performed simultaneously and independently. In addition, the first electrode E1 can be continuous with the second electrode E2. The continuous first electrode E1 and second electrode E2 are included in a so-called “common electrode” or a “counter electrode”. The sensor electrode SE may be formed from the same layer as the pixel electrode PE.

In short, each of the layers constituting the light-emitting element 3 may extend to the light-receiving sensor 4, except for the pixel electrode PE and the light-emitting layer EM.

The light-emitting device 1 may further include an edge cover film EC that covers at least a part of the edge of the pixel electrode PE, and that has an opening AP overlapping the part of the pixel electrode PE and at least a part of the sensor electrode SE in a plan view. The edge cover film EC may cover at least a part of the edge of the sensor electrode SE.

The light-emitting element 3 may be a light-emitting diode, and the light-receiving sensor 4 may be a photodiode. The light-emitting element 3 may be an organic light-emitting diode (OLED) in which the light-emitting layer EM contains an organic light-emitting material, or may be a quantum dot light-emitting diode (QLED) in which the light-emitting layer EM contains quantum dots. The light-receiving sensor 4 may be an organic photodiode in which the first generating layer G1 and the second generating layer G2 contain an organic material, or may be an inorganic photodiode in which the first generating layer G1 and the second generating layer G2 contain an inorganic material.

The light-emitting device 1 may further include a substrate CP, and the light-emitting element 3 and the light-receiving sensor 4 may be located between the substrate CP and the optical waveguide 2. The substrate CP may be a circuit board including a support substrate BP and a circuit layer CL formed on the support substrate.

The optical waveguide 2 can guide a part of the light emitted by the light-emitting element 3 to the light-receiving sensor 4. Of the light generated in the light-emitting layer EM, the light incident on the optical waveguide 2 at an angle smaller than the critical angle traverses the optical waveguide 2 and is emitted to the outside of the light-emitting device 1. On the other hand, light incident on the optical waveguide 2 at an angle larger than the critical angle passes through the optical waveguide 2 and is guided to the light-receiving sensor 4. Advantageously, therefore, the light-receiving sensor 4 introduces light that is not easily extracted to the outside, and therefore does not cause a reduction in the light extraction efficiency.

The optical waveguide 2 may include at least a part of a sealing layer TFE sealing the light-emitting element 3 and the light-receiving sensor 4, or may include the entire sealing layer TFE. Furthermore, one or more layers located between the substrate CP and the sealing layer TFE may help to guide part of the light emitted by the light-emitting element 3 to the light-receiving sensor 4. In the example illustrated in FIG. 2, the entire sealing layer TFE is the optical waveguide 2. Therefore, the reference symbol is represented as “TFE (2)”.

The sealing layer TFE may be a thin film sealing layer, and may include, for example, a first inorganic sealing film N1, a second inorganic sealing film N2, and an organic sealing film O1 disposed between the first inorganic sealing film N1 and the second inorganic sealing film N2. The first inorganic sealing film N1 and the second inorganic sealing film N2 may include, for example, one or more selected from the group consisting of silicon nitride and silicon oxide. The organic sealing film O1 is preferably made of a transparent material having a refractive index smaller than that of the first inorganic sealing film N1 and the second inorganic sealing film N2. For example, when the first inorganic sealing film N1 and the second inorganic sealing film N2 are made of silicon oxide, the organic sealing film O1 may include one or more selected from the group consisting of polyacrylic resins.

### Circuit Configuration

The light-emitting device 1 may further include a pixel circuit C1 that controls the light emission of the light-emitting elements 3 by controlling a voltage or current to be applied, and a light-receiving circuit C2 that detects the light reception of the light-receiving sensor 4 by measuring a generated electromotive force. The circuit configuration of the light-receiving circuit C2 may be the same as or different from the circuit configuration of the pixel circuit C1. The pixel circuit C1 and the light-receiving circuit C2 may be formed in the substrate CP.

The circuit configuration of a certain circuit being the same as the circuit configuration of another certain circuit means that circuit elements included in the former circuit are equivalent to circuit elements included in the latter circuit, and connection relationships between the circuit elements in the former circuit are equivalent to connection relationships between the circuit elements in the latter circuit. Here, the circuit elements and the connection relationships are considered to be equivalent even if characteristic values thereof are different. For example, two transistors having different threshold values and resistance values are the equivalent circuit elements. Further, for example, two capacitors having different capacitances and geometric sizes are the equivalent circuit elements. Further, for example, a light-emitting diode and a photodiode are the equivalent circuit elements. Further, for example, parasitic capacitance and wiring line resistance may be ignored.

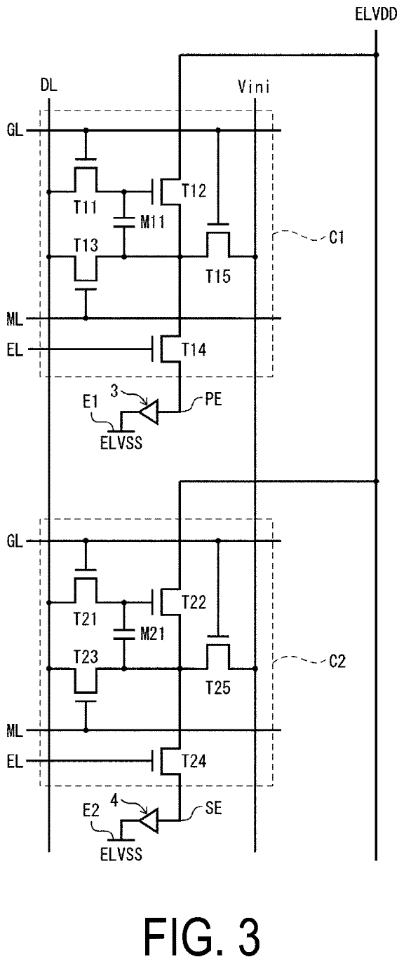

FIG. 3 is a circuit diagram illustrating an example in which the pixel circuit and the light-receiving circuit illustrated in FIG. 2 have the same circuit configuration. As illustrated in FIG. 3, the pixel circuit C1 may include a write transistor T11, an amplification transistor T12, a read transistor T13, a light-emitting transistor T14, an initialization transistor T15, and a storage capacitor M11. Similarly, the light-receiving circuit C2 may include a write transistor T21, an amplification transistor T22, a read transistor T23, a light-receiving transistor T24, an initialization transistor T25, and a storage capacitor M21.

A gate signal line GL connected to the pixel circuit C1 and the gate signal line GL connected to the light-receiving circuit C2 are separate from each other, and can be independently supplied with control signals. A monitor signal line ML connected to the pixel circuit C1 and the monitor signal line ML connected to the light-receiving circuit C2 are separate from each other and can be independently supplied with control signals.

A light-emitting signal line EL connected to the pixel circuit C1 and the light-emitting signal line EL connected to the light-receiving circuit C2 may be separated from each other or may be connected to each other. The pixel circuit C1 and the light-receiving circuit C2 may share the light-emitting signal line EL. The pixel circuit C1 and the light-receiving circuit C2 may share power lines for supplying a drain-side power source potential ELVDD, a source-side power source potential ELVSS, and an initialization potential Vini.

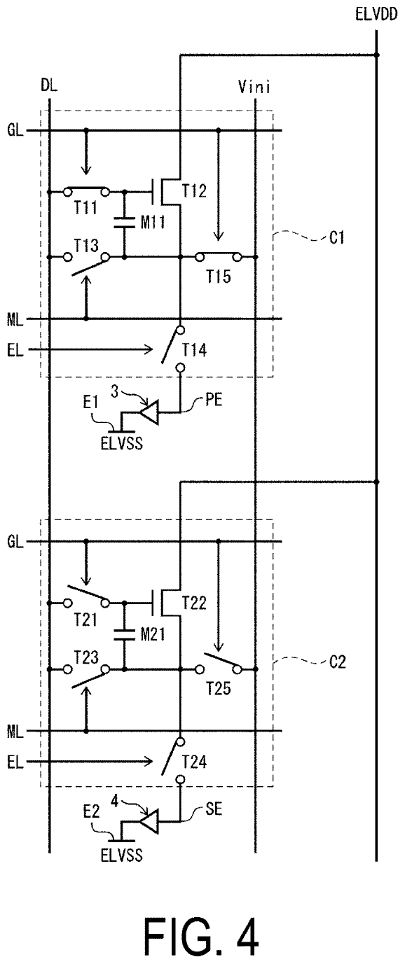

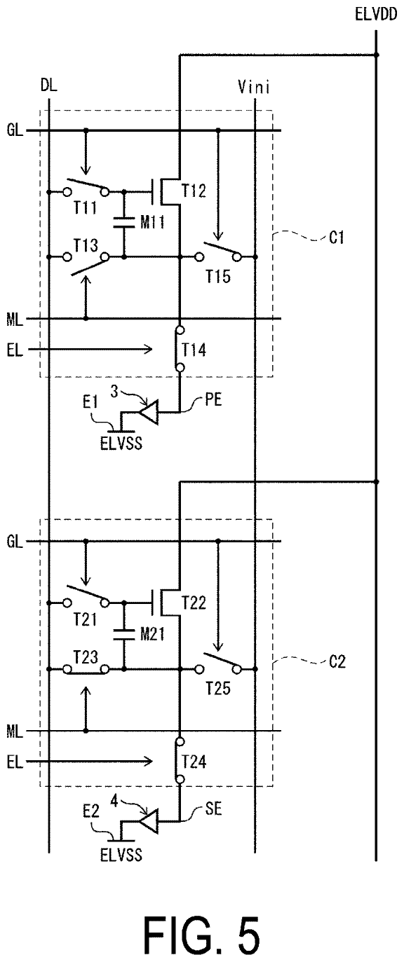

FIG. 4 is a circuit diagram illustrating an example of an operation when data is written from the data line to the pixel circuit, in the circuit configuration illustrated in FIG. 3. FIG. 5 is a circuit diagram illustrating an example of an operation when a light-emitting element emits light, in the circuit configuration illustrated in FIG. 3. FIGS. 4 and 5 illustrate the write transistors T11 and T21, the read transistors T13 and T23, the light-emitting transistor T14 and the light-receiving transistor T24, and the initialization transistors T15 and T25 as switching elements.

As illustrated in FIG. 4, after the pixel circuit C1 and the light-receiving circuit C2 are initialized, in the pixel circuit C1, the write transistor T11 and the initialization transistor T15 are brought into a conductive state, and the read transistor T13 and the light-emitting transistor T14 are brought into a non-conductive state. As a result, it is possible to write data from the data signal line DL to a gate electrode of the amplification transistor T12 and to an electrode on one side of the storage capacitor M11 through the write transistor T11, and to write the initialization potential Vini to the electrode on the opposite side of the storage capacitor M11 through the initialization transistor T15. During the writing to the storage capacitor M11, the write transistor T21 and the read transistor T23 in the light-receiving circuit C2 may be brought into a non-conductive state.

As illustrated in FIG. 5, subsequently, in the pixel circuit C1, the write transistor T11, the read transistor T13, and the initialization transistor T15 are brought into a non-conductive state, and the light-emitting transistor T14 is brought into a conductive state. As a result, the drain-side power source potential ELVDD can be applied to the pixel electrode PE through the amplification transistor T12 and the light-emitting transistor T14, to cause the light-emitting element 3 to emit light. The voltage applied to the pixel electrode PE and a light emission luminance of the light-emitting element 3 are determined in accordance with a gate voltage of the amplification transistor T12, i.e., in accordance with the data written to the electrode on the one side of the storage capacitor M11. During the light emission of the light-emitting element 3, in the light-receiving circuit C2, the write transistor T21 and the initialization transistor T25 may be brought into a non-conductive state, and the read transistor T23 and the light-receiving transistor T24 may be brought into a conductive state. In this way, a charge generated in the light-receiving sensor 4 can be output to the data signal line DL through the sensor electrode SE, the light-receiving transistor T24, and the read transistor T23.

Alternatively, during the light emission of the light-emitting element 3, in the light-receiving circuit C2, the write transistor T21, the read transistor T23, and the initialization transistor T25 may be brought into a non-conductive state, and the light-receiving transistor T24 may be brought into a conductive state. As a result, a charge generated in the light-receiving sensor 4 can be accumulated in an electrode on an opposite side of the storage capacitor M21 through the sensor electrode SE and the light-receiving transistor T24. After the light-emitting element 3 emits light, the read transistor T23 is brought into a conductive state, and the charge stored in the storage capacitor M21 can be output to the data signal line DL through the read transistor T23.

The pixel circuit C1 and the light-receiving circuit C2 may share some of the circuit elements. For example, the pixel circuit C1 and the light-receiving circuit C2 may share a single transistor as the initialization transistors T15 and T25.

The pixel circuit C1 and the light-receiving circuit C2 may share some of the wiring lines connected to each other. For example, the light-emitting device 1 may further include the data signal line DL for supplying data, to the pixel circuit C1, that specifies the light emission luminance of the light-emitting element 3, and the light-receiving circuit C2 may output a detection result of the light-receiving sensor 4 through the data signal line DL.

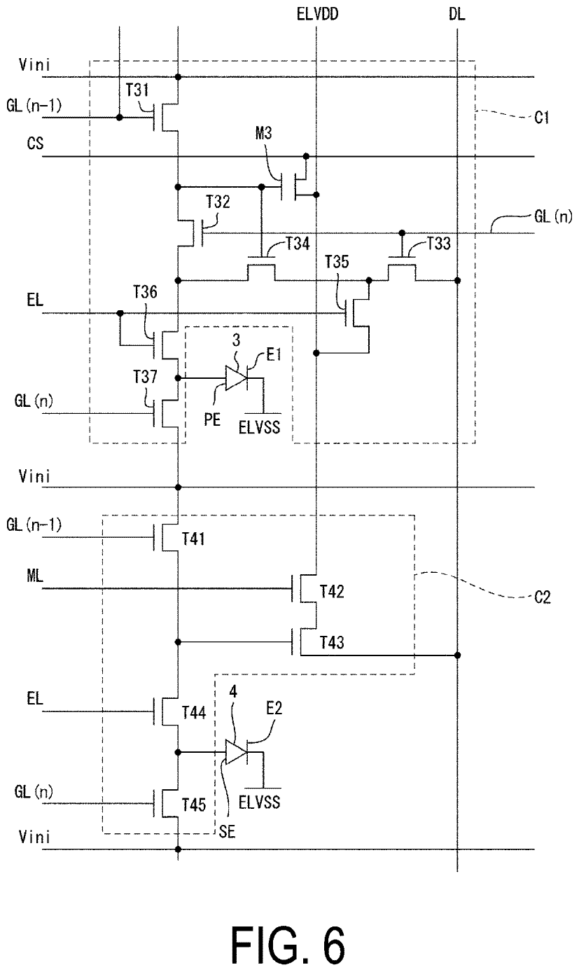

FIG. 6 is a circuit diagram illustrating an example in which the pixel circuit and the light-receiving circuit illustrated in FIG. 2 have different circuit configurations. As illustrated in FIG. 6, the pixel circuit C1 may include initialization transistors T31 and T37, write transistors T32 and T33, an amplification transistor T34, light-emitting transistors T35 and T36, and a storage capacitor M3. The light-receiving circuit C2 may include initialization transistors T41 and T45, an amplification transistor T43, a read transistor T42, and a light-receiving transistor T44.

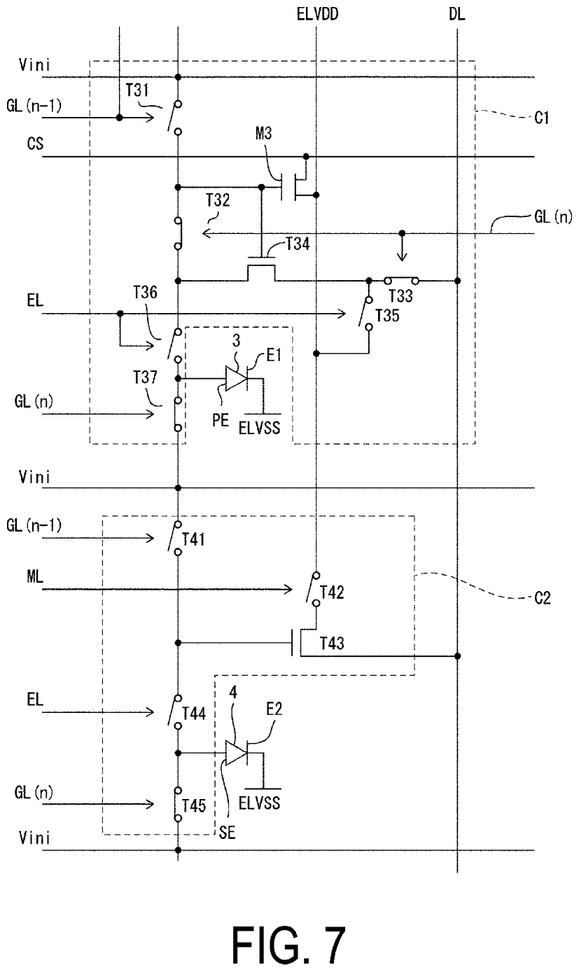

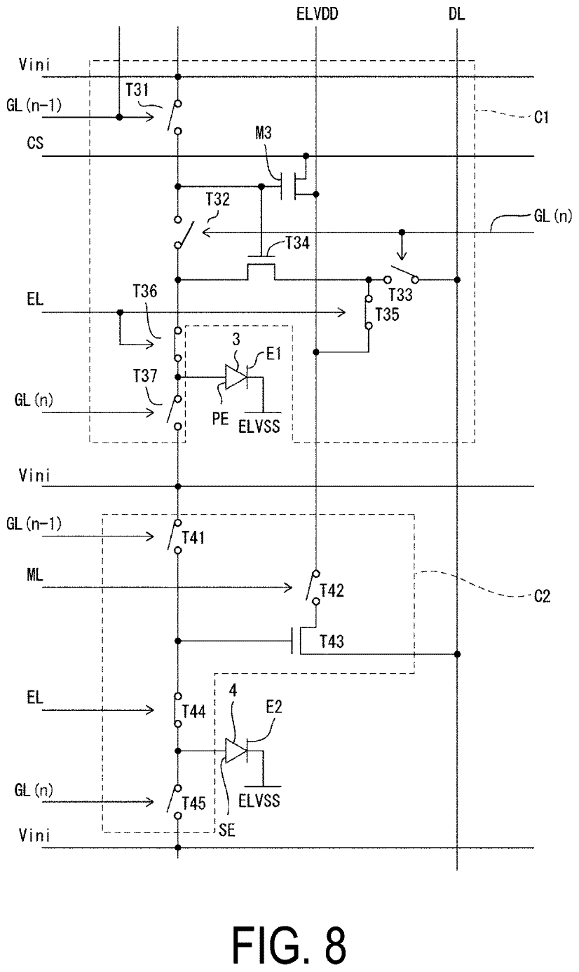

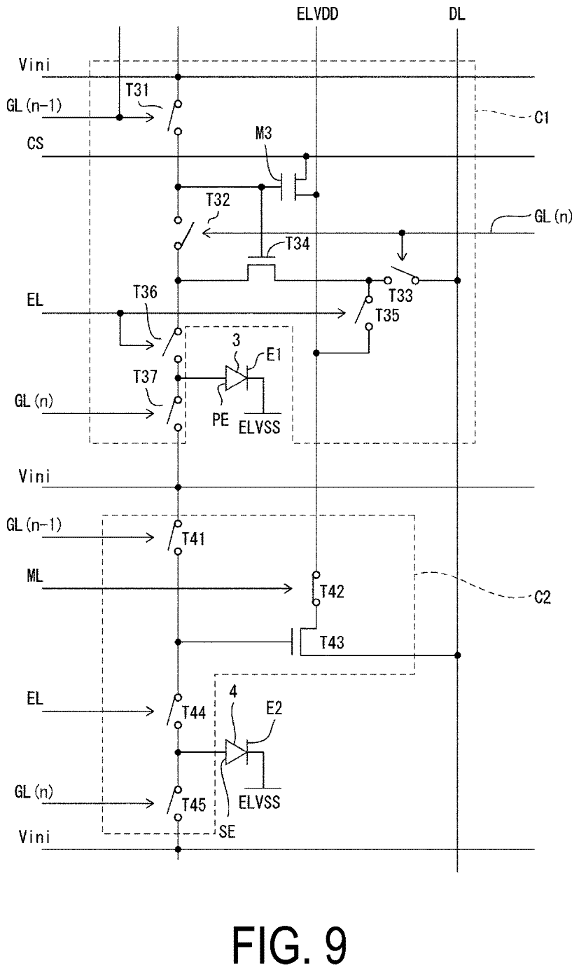

FIG. 7 is a circuit diagram illustrating an example of an operation when data is written from the data line to the pixel circuit, in the circuit configuration illustrated in FIG. 6. FIG. 8 is a circuit diagram illustrating an example of an operation when the light-emitting element emits light, in the circuit configuration illustrated in FIG. 6. FIG. 9 is a circuit diagram illustrating an example of an operation when data is read from the light-receiving circuit to the data line, in the circuit configuration illustrated in FIG. 6. FIGS. 7, 8, and 9 illustrate the initialization transistors T31, T37, T41, and T45, the write transistors T32 and T33, the light-emitting transistors T35 and T36, the read transistor T42, and the light-receiving transistor T44 as switching elements.

As illustrated in FIG. 7, after the pixel circuit C1 and the light-receiving circuit C2 are initialized, in the pixel circuit C1, the write transistors T32 and T33 are brought into a conductive state, and the initialization transistor T31 and the light-emitting transistors T35 and T36 are brought into a non-conductive state. As a result, it is possible to write data from the data signal line DL to a gate electrode of the amplification transistor T34 and an electrode on one side of the storage capacitor M3 through the write transistor T33, the amplification transistor T34, and the write transistor T21. During the writing to the storage capacitor M3, the read transistor T42 in the light-receiving circuit C2 may be brought into a non-conductive state.

As illustrated in FIG. 8, subsequently, in the pixel circuit C1, the initialization transistors T31 and T37 and the write transistors T32 and 33 are brought into a non-conductive state, and the light-emitting transistors T35 and T36 are brought into a conductive state. As a result, the drain-side power source potential ELVDD can be applied to the pixel electrode PE through the light-emitting transistor T35, the amplification transistor T34, and the light-emitting transistor T36, to cause the light-emitting element 3 to emit light. During the light emission of the light-emitting element 3, in the light-receiving circuit C2, the initialization transistors T41 and T45 and the read transistor T42 may be brought into a non-conductive state, and the light-receiving transistor T44 may be brought into a conductive state. In this way, the charge generated in the light-receiving sensor 4 can be accumulated in a gate electrode of the amplification transistor T44 through the sensor electrode SE and the light-receiving transistor T43.

As illustrated in FIG. 9, after the light-emitting element 3 emits light, in the light-receiving circuit C2, the read transistor T42 is brought into a conductive state, and the drain-side power source potential EL VDD can be output to the data line DL through the read transistor T42 and the amplification transistor T43. The voltage output to the data line DL is determined in accordance with a gate voltage of the amplification transistor T43, that is, in accordance with an amount of charge accumulated in the gate electrode of the amplification transistor T43.

The pixel circuit C1 and the light-receiving circuit C2 may share some of the circuit elements. For example, the pixel circuit C1 and the light-receiving circuit C2 may share a single transistor as the initialization transistors T37 and T41. The pixel circuit C1 and the light-receiving circuit C2 may share some of the wiring lines connected to each other. For example, the pixel circuit C1 and the light-receiving circuit C2 may share the data signal line DL.

### Second Embodiment

Another embodiment of the disclosure will be described below. Further, members having the same functions as those of the members described in the above-described embodiment will be denoted by the same reference numerals and signs, and a description thereof will not be repeated for convenience of description.

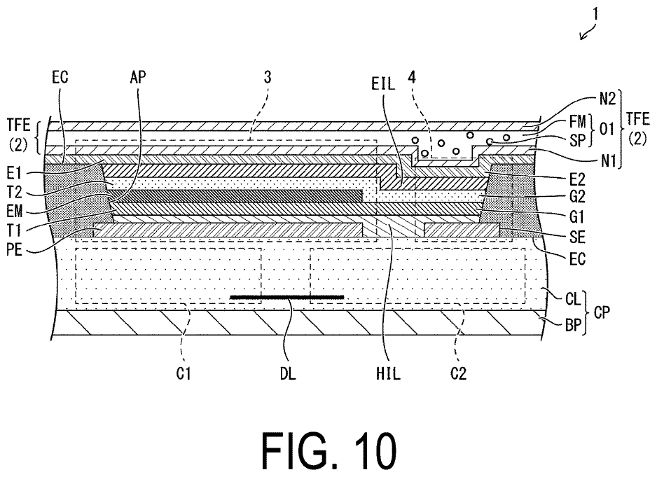

FIG. 10 is a schematic cross-sectional view illustrating an example of a configuration of the light-emitting device according to an embodiment of the disclosure. As illustrated in FIG. 10, the optical waveguide 2 may include scatterers SP that overlap the light-receiving sensor 4 in a plan view. The scatterers SP may be distributed so as not to overlap the light-emitting element 3 in a plan view. For example, the organic sealing film O1 may include a plurality of the scatterers SP and a filling material FM filling spaces between the scatterers SP.

### Third Embodiment

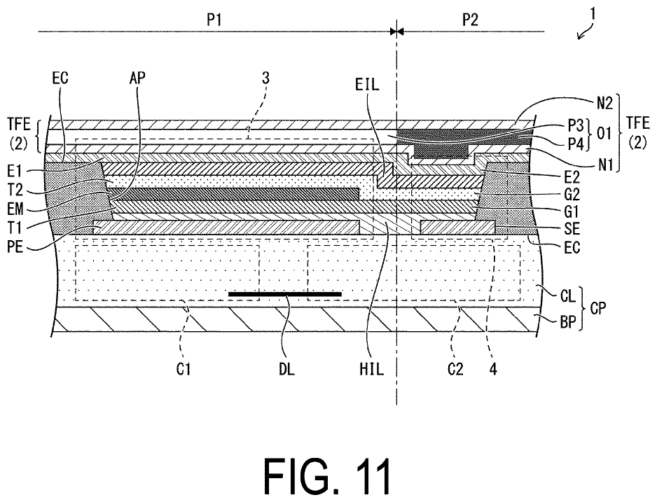

FIG. 11 is a schematic cross-sectional view illustrating an example of a configuration of the light-emitting device according to an embodiment of the disclosure. As illustrated in FIG. 11, the optical waveguide 2 may include a first section P1 that overlaps the light-emitting element 3 in a plan view, and a second section P2 that overlaps the light-receiving sensor 4 in a plan view and has a higher refractive index than that of the first section P1.

For example, the organic sealing film O1 may include a section P3 included in the first section P1 and made of a first transparent material, and a section P4 included in the second section P2 and made of a second transparent material having a higher refractive index than that of the first transparent material. Each of the first inorganic sealing film N1 and the second inorganic sealing film N2 may be formed of the same material over the first section P1 and the second section P2. In this example, the average refractive index of the second section P2 is greater than the average refractive index of the first section P1.

The third embodiment can be combined with the second embodiment described above. For example, the scatterers SP may be distributed in the second section P2 of the optical waveguide 2 (or the section P4 of the organic sealing film O1).

### Fourth Embodiment

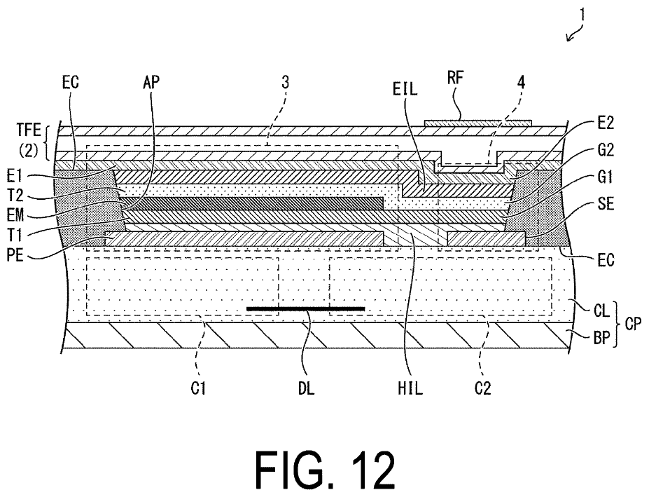

FIG. 12 is a schematic cross-sectional view illustrating an example of a configuration of the light-emitting device according to an embodiment of the disclosure. As illustrated in FIG. 12, the light-emitting device 1 may further include a light reflective portion RF that overlaps the light-receiving sensor 4 in a plan view and reflects light propagating through the optical waveguide 2. The light reflective portion RF is provided so as not to overlap the light-emitting element 3 in a plan view.

The fourth embodiment can be combined with any one of the first to third embodiments described above.

### Fifth Embodiment

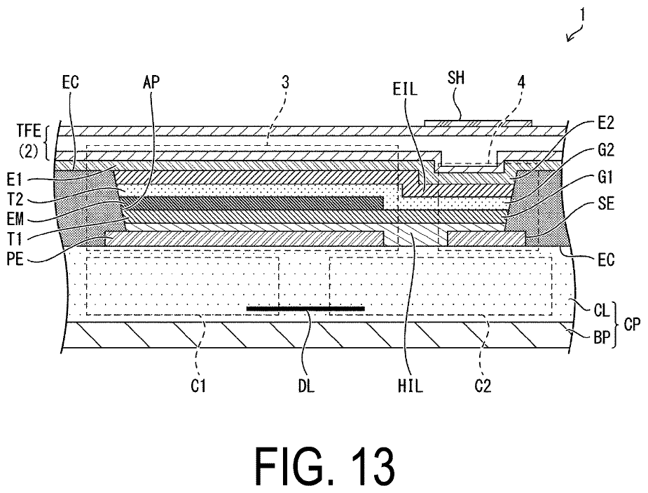

FIG. 13 is a schematic cross-sectional view illustrating an example of a configuration of the light-emitting device according to an embodiment of the disclosure. As illustrated in FIG. 13, the light-emitting device 1 may further include a light blocking portion SH that overlaps the light-receiving sensor 4 in a plan view and that blocks external light. The light blocking portion SH is provided so as not to overlap the light-emitting element 3 in a plan view.

The fifth embodiment can be combined with any one of the first to third embodiments described above. Further, the fifth embodiment can be combined with the fourth embodiment described above. For example, the light blocking portion SH may function as the light reflective portion RF. Further, for example, the light reflective portion RF may be located between the light blocking portion SH and the optical waveguide 2.

### Sixth Embodiment

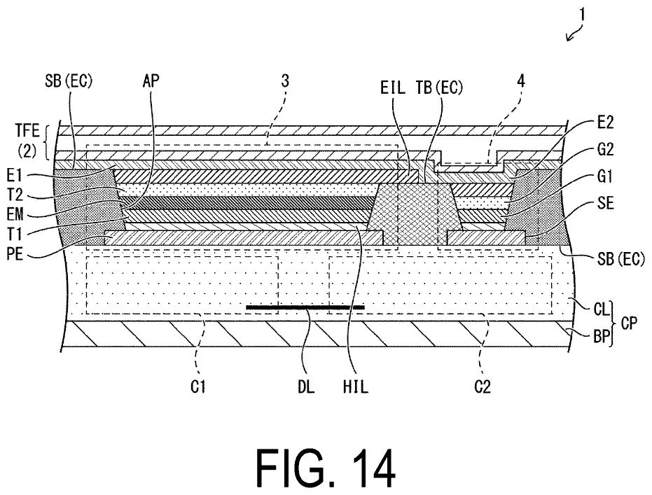

FIG. 14 is a schematic cross-sectional view illustrating an example of a configuration of the light-emitting device according to an embodiment of the disclosure. As illustrated in FIG. 14, the light-emitting device 1 may further include a light blocking bank SB that surrounds the light-emitting element 3 and the light-receiving sensor 4 in a plan view and that blocks external light. The light blocking bank SB may be included in the edge cover film EC. The light blocking bank SB may be a black bank that absorbs light, and may be formed of a resin to which a pigment is added. The pigment may contain carbon powder.

Additionally or alternatively, the light-emitting device 1 may further include a light transmitting bank TB which is located between the light-emitting element 3 and the light-receiving sensor 4 and through which the light emitted by the light-emitting element 3 can pass. The light transmitting bank TB may be included in the edge cover film EC.

The sixth embodiment can be combined with any one of the first to fifth embodiments described above.

### Seventh Embodiment

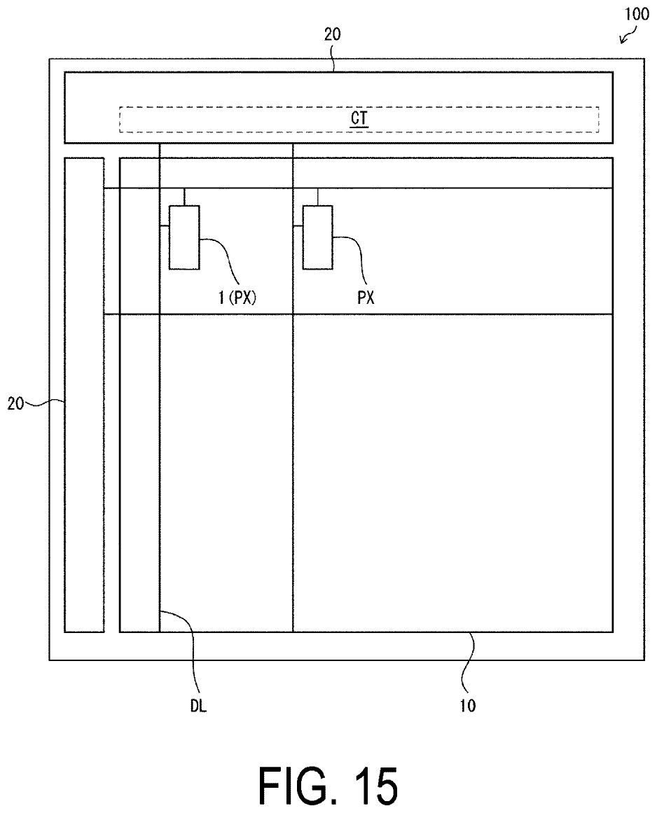

FIG. 15 is a schematic view illustrating an example of a configuration of a display device according to an embodiment of the disclosure. As illustrated in FIG. 15, a display device 100 includes at least one of the light-emitting devices 1. The display device 100 includes, for example, a display portion 10 including a plurality of subpixels PX, and a drive circuit 20 that drives the display portion 10. At least one of the subpixels PX includes the light-emitting device 1. The light-emitting device 1 included in the display device 100 may be the light-emitting device 1 according to any one of the first to sixth embodiments described above, may be the light-emitting device 1 obtained by combining any number of the light-emitting devices 1 according to the first to sixth embodiments described above, or may be the light-emitting device 1 obtained by changing or improving the first to sixth embodiments described above.

The display device 100 may further include a control unit CT that controls the voltage or current to be applied to the light-emitting element 3, in order to compensate for deterioration of the light-emitting element 3, based on the detection result of the light-receiving sensor 4. As a result, a decrease in the luminance of the light-emitting element 3 is compensated, and a display quality of the display device 100 can be maintained and improved. The control unit CT may be incorporated in the drive circuit 20.

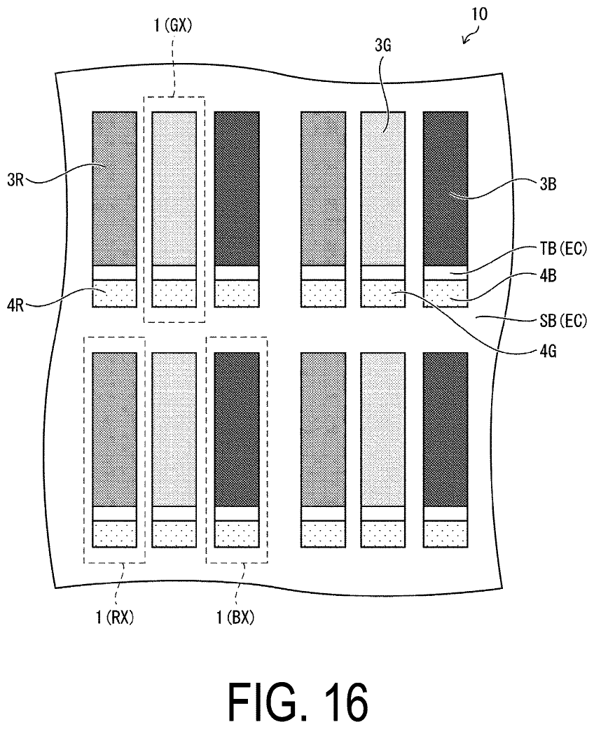

FIG. 16 is a schematic plan view illustrating an example of a configuration of the display portion illustrated in FIG. 15. As illustrated in FIG. 16, the display portion 10 may include a red subpixel RX, a green subpixel GX, and a blue subpixel BX. The red subpixel RX includes a light-emitting element 3R that emits red light, a light-receiving sensor 4R that detects light emitted from the light-emitting element 3R, and the optical waveguide 2 (not illustrated). The green subpixel GX includes a light-emitting element 3G that emits green light, a light-receiving sensor 4G that detects light emitted from the light-emitting element 3G, and the optical waveguide 2 (not illustrated). The blue subpixel BX includes a light-emitting element 3B that emits blue light, a light-receiving sensor 4B that detects light emitted from the light-emitting element 3B, and the optical waveguide 2 (not illustrated).

The red subpixel RX, the green subpixel GX, and the blue subpixel BX may include the edge cover film EC, and the respective edge cover films EC may be continuous with each other. The edge cover film EC may include the light transmitting bank TB and the light blocking bank SB.

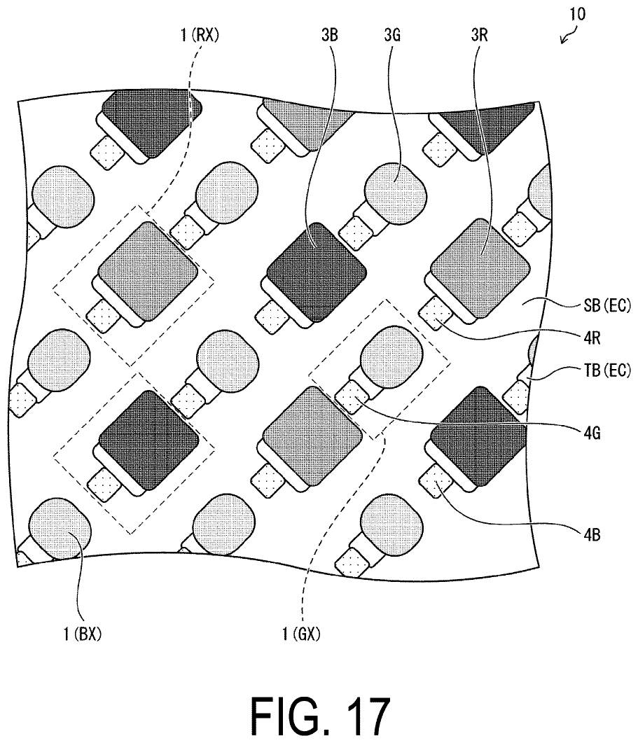

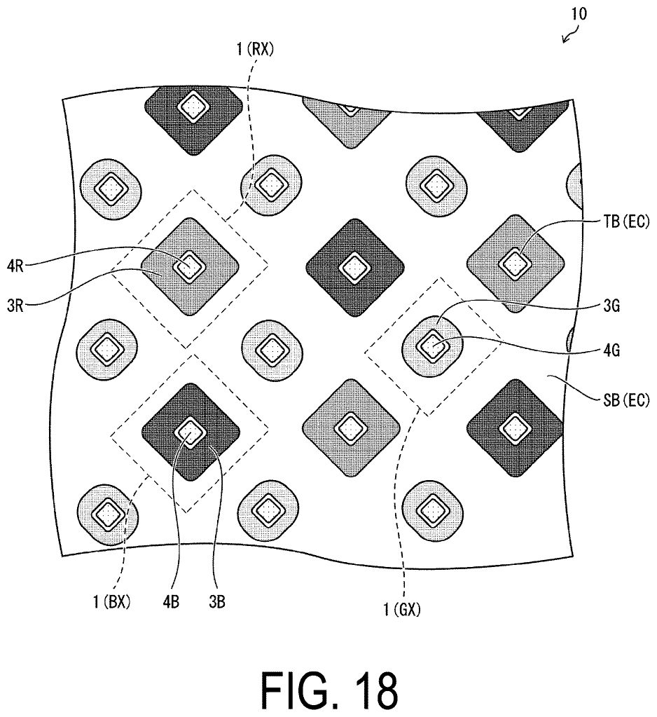

FIG. 17 is a schematic plan view illustrating another example of a configuration of the display portion illustrated in FIG. 15. The red subpixels RX, the green subpixels GX, and the blue subpixels BX may be disposed as illustrated in FIG. 17. FIG. 18 is a schematic plan view illustrating yet another example of a configuration of the display portion illustrated in FIG. 15. As illustrated in FIG. 18, the light-emitting elements 3R, 3G, and 3B may surround corresponding light-receiving sensors 4R, 4G, and 4B, respectively. The configuration of the display portion 10 is not limited to the examples illustrated in FIGS. 16 to 18.

### Eighth Embodiment

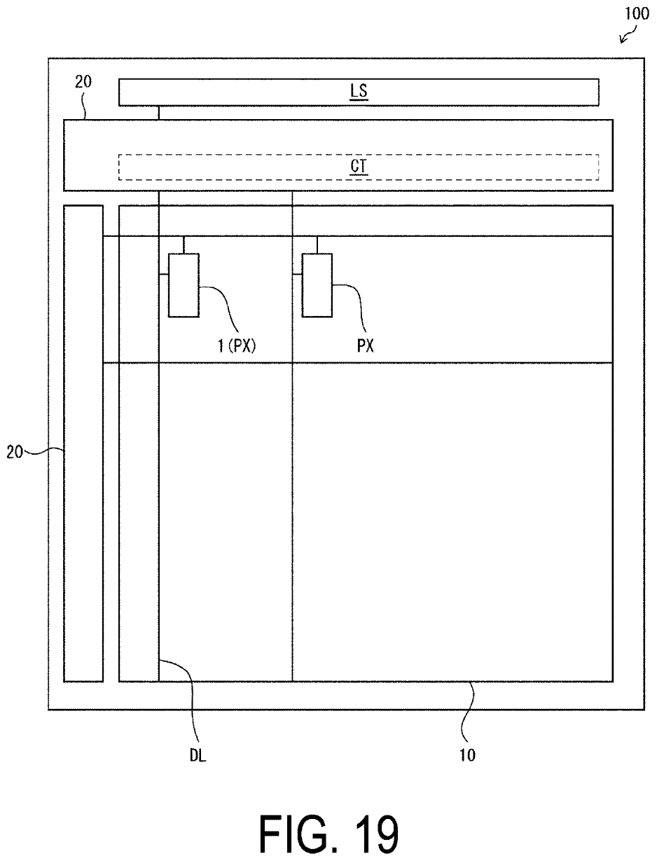

FIG. 19 is a schematic view illustrating an example of a configuration of the display device according to an embodiment of the disclosure. As illustrated in FIG. 19, the display device 100 includes at least one of the light-emitting devices 1. The display device 100 may further include an external light sensor LS, and the control unit CT that controls the voltage or current applied to the light-emitting element 3, in order to compensate for the deterioration of the light-emitting element 3, based on the detection result of the light-receiving sensor 4 and the detection result of the external light sensor LS. Accordingly, the decrease in the luminance of the light-emitting element 3 is compensated while taking external light into consideration, and the display quality of the display device 100 can be maintained and improved. The control unit CT may be incorporated in the drive circuit 20.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. A light-emitting device comprising:
an optical waveguide;
a light-emitting element overlapping the optical waveguide in a plan view; and
a light-receiving sensor overlapping the optical waveguide and not overlapping the light-emitting element in a plan view.

2. The light-emitting device according to claim 1,
wherein the light-emitting element includes
a pixel electrode overlapping the optical waveguide in a plan view,
a first electrode located between the optical waveguide and the pixel electrode, and
a light-emitting layer located between the pixel electrode and the first electrode, and
the light-receiving sensor includes
a sensor electrode overlapping the optical waveguide in a plan view and not overlapping the pixel electrode in a plan view,
a second electrode located between the optical waveguide and the sensor electrode,
a first generating layer in which a first carrier is generated, the first generating layer being located between the sensor electrode and the second electrode, and
a second generating layer in which a second carrier having a polarity opposite to a polarity of the first carrier is generated, the second generating layer being located between the sensor electrode and the second electrode.

3. The light-emitting device according to claim 2,
wherein the first generating layer is in direct contact with the second generating layer.

4. The light-emitting device according to claim 2,
wherein the light-emitting element includes
a first transport layer located between the pixel electrode and the first electrode and configured to transport the first carrier, and
a second transport layer located between the pixel electrode and the first electrode and configured to transport the second carrier,
the first transport layer is formed of the same layer made of the same material as the first generating layer, and
the second transport layer is formed of the same layer made of the same material as the second generating layer.

5. The light-emitting device according to claim 4,
wherein the first transport layer is continuous with the first generating layer, and
the second transport layer is continuous with the second generating layer.

6. The light-emitting device according to claim 2,
wherein each of the first generating layer and the second generating layer extends between the pixel electrode and the first electrode.

7. The light-emitting device according to claim 4,
wherein the first transport layer is located between the pixel electrode and the light-emitting layer,
a first structure between the pixel electrode and the first transport layer is the same as a second structure between the sensor electrode and the first generating layer,
the second transport layer is located between the first electrode and the light-emitting layer, and
a third structure between the first electrode and the second transport layer is the same as a fourth structure between the second electrode and the second generating layer.

8. The light-emitting device according to claim 7,
wherein the first structure is continuous with the second structure, and
the third structure is continuous with the fourth structure.

9. The light-emitting device according to claim 2,
wherein the sensor electrode is electrically separated from the pixel electrode, and
the second electrode is electrically connected to the first electrode.

10. The light-emitting device according to claim 2,
wherein the sensor electrode is formed of the same layer as the pixel electrode.

11. The light-emitting device according to claim 2, further comprising:
an edge cover film covering at least a part of an edge of the pixel electrode and being provided with an opening overlapping a part of the pixel electrode and at least a part of the sensor electrode in a plan view.

12-14. (canceled)

15. The light-emitting device according to claim 1,
wherein the optical waveguide includes at least a part of a sealing layer sealing the light-emitting element and the light-receiving sensor.

16. The light-emitting device according to claim 1,
wherein the optical waveguide includes a scatterer overlapping the light-receiving sensor in a plan view.

17. The light-emitting device according to claim 1,
wherein the optical waveguide includes
a first section overlapping the light-emitting element in a plan view, and
a second section overlapping the light-receiving sensor in a plan view and having a refractive index higher than a refractive index of the first section.

19. The light-emitting device according to claim 1, further comprising:
a light blocking portion overlapping the light-receiving sensor in a plan view and being configured to block external light.

20. The light-emitting device according to claim 1, further comprising:
a light blocking bank surrounding the light-emitting element and the light-receiving sensor in a plan view and being configured to block external light.

21. The light-emitting device according to claim 1, further comprising:
a pixel circuit configured to control light emission of the light-emitting element; and
a light-receiving circuit configured to detect light reception of the light-receiving sensor,
wherein a circuit configuration of the light-receiving circuit is the same as a circuit configuration of the pixel circuit.

22. The light-emitting device according to claim 1, further comprising:
a pixel circuit configured to control light emission of the light-emitting element; and
a light-receiving circuit configured to detect light reception of the light-receiving sensor,
wherein a circuit configuration of the light-receiving circuit is different from a circuit configuration of the pixel circuit.

23. The light-emitting device according to claim 21,
wherein the pixel circuit and the light-receiving circuit share a single transistor as an initialization transistor.

24. The light-emitting device according to claim 21, further comprising:
a data signal line configured to supply, to the pixel circuit, data specifying a light emission luminance of the light-emitting element,
wherein the light-receiving circuit outputs a detection result of the light-receiving sensor through the data signal line.

25-27. (canceled)
